(19) United States
(12) Patent Application Publication
(10) Pub. No.: US 2024/0324178 A1
(43) Pub. Date: Sep. 26, 2024

(54) SEMICONDUCTOR DEVICE AND SEMICONDUCTOR MEMORY DEVICE

(71) Applicant: Kioxia Corporation, Tokyo (JP)

(72) Inventors: Kasumi OKABE, Nagoya Aichi (JP); Akifumi GAWASE, Kuwana Mie (JP); Kazuhiro KATONO, Mie Mie (JP); Kotaro NODA, Yokkaichi Mie (JP); Takanori AKITA, Yokkaichi Mie (JP); Takahiro FUJII, Nagoya Aichi (JP)

(21) Appl. No.: 18/593,978

(22) Filed: Mar. 4, 2024

(30) Foreign Application Priority Data
Mar. 24, 2023 (JP) 2023-047816

(51) Int. Cl. H10B 12/00

(52) U.S. Cl. CPC H10B 12/33; H10B 12/50

(57) ABSTRACT

A semiconductor device includes a first electrode, an oxide semiconductor layer electrically connected to the first electrode and disposed above the first electrode, a gate electrode facing the oxide semiconductor layer with an insulating film interposed therebetween, and a second electrode including a first conductive layer electrically connected to the oxide semiconductor layer and disposed above the oxide semiconductor layer, the first conductive layer containing oxygen, indium, and tin. The second electrode further includes a second conductive layer in contact with the first conductive layer and containing oxygen and a first metal and a third conductive layer in contact with the second conductive layer and containing the first metal.

### CROSS-REFERENCE TO RELATED APPLICATION(S)

This application is based upon and claims the benefit of priority from Japanese Patent Application No. 2023-047816, filed Mar. 24, 2023, the entire contents of which are incorporated herein by reference.

### FIELD

Embodiments described herein relate generally to a semiconductor device and a semiconductor memory device.

### BACKGROUND

Semiconductor elements with an oxide of a metal including indium and tin as an electrode are known. In the process of producing a semiconductor element, a problem caused by an oxide of a metal including indium (In) and tin (Sn) may occur.

### DESCRIPTION OF THE DRAWINGS

FIG. 1 is a circuit diagram illustrating a configuration example of a circuit of a semiconductor memory device according to a first embodiment.

FIG. 2 is a schematic cross-sectional view illustrating a configuration example of the semiconductor memory device according to the first embodiment.

FIG. 3 is a schematic cross-sectional view illustrating a main part of a semiconductor memory device according to comparative example.

FIG. 4 is a schematic cross-sectional view illustrating a main part of the semiconductor memory device according to the first embodiment.

FIG. 5 is a diagram illustrating adherence between an ITO layer and a TiO layer in the first embodiment.

FIG. 6 is a schematic cross-sectional view illustrating a main part of a semiconductor memory device according to a second embodiment.

FIG. 7 is a diagram illustrating a change in an indium concentration and a titanium concentration in an intermediate conductive layer according to the second embodiment.

### DETAILED DESCRIPTION

Embodiments provide a semiconductor device and a semiconductor memory device that can reduce the problem caused by an oxide of a metal including indium and tin.

In general, according to one embodiment, a semiconductor device includes a first electrode, an oxide semiconductor layer electrically connected to the first electrode and disposed above the first electrode, a gate electrode facing the oxide semiconductor layer with an insulating film interposed therebetween, and a second electrode including a first conductive layer electrically connected to the oxide semiconductor layer and disposed above the oxide semiconductor layer, the first conductive layer containing oxygen, indium, and tin. The second electrode further includes a second conductive layer in contact with the first conductive layer and containing oxygen and a first metal and a third conductive layer in contact with the second conductive layer and containing the first metal.

According to one embodiment, a semiconductor memory device includes the semiconductor device, a third electrode electrically connected to the first electrode, a fourth electrode facing the third electrode, and a dielectric film between the third electrode and the fourth electrode.

Hereinafter, embodiments will be described with reference to the accompanying drawings. For ease of understanding the description, the same elements are given the same reference numerals and symbols in each drawing as much as possible, and duplicated description is omitted or simplified.

In each drawing, X, Y, and Z axes may be used. The X, Y, and Z axes form right-handed three-dimensional orthogonal coordinates. Hereinafter, the arrow direction of the X axis is referred to as a +X-axial direction, and a direction opposite to the arrow direction of the X axis is referred to as a −X-axial direction. The same applies to the other axes. Further, a +Z-axial direction and a −Z-axial direction are referred to as “upward (upwardly)” and “downward (downwardly)”, respectively. Further, a plane perpendicular to the X, Y, or Z axis is referred to as a YZ plane, a ZX plane, or an XY plane, respectively. Furthermore, the Z-axial direction is referred to as “upward or downward direction (upwardly or downwardly)”. The terms “upward (upwardly)”, “downward (downwardly)”, and “upward or downward direction (upwardly or downwardly)” are terms indicating a relative positional relationship in the drawings, but not necessarily terms defining a direction based on the vertical direction.

For case of understanding the description, the dimension and the like of elements shown in each drawing may be shown as those different from the actual dimension unless otherwise specifically described.

The term “connection” as used herein includes not only a physical connection but also an electrical connection, and unless otherwise specified, includes not only a direct connection but also an indirect connection that is connection through one or more other objects.

The term “being on or above” an element as used herein includes not only being in contact with the element, but also being above the element through other elements unless otherwise specified. The same applies to the term “being under or below” an element.

### First Embodiment

The first embodiment is directed to a semiconductor memory device 101 including a memory cell array in which a plurality of memory cells of oxide semiconductor-random access memories (OS-RAMs) are arranged.

### Circuit Configuration of Semiconductor Memory Device

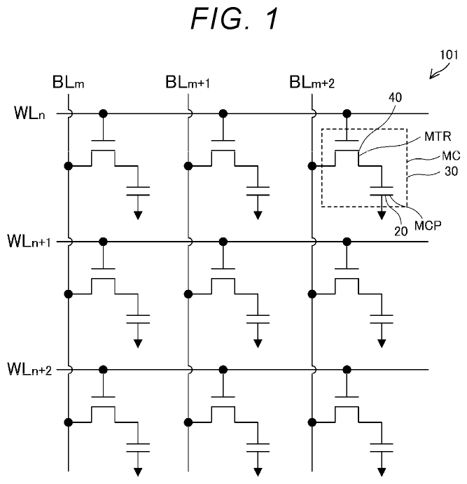

FIG. 1 illustrates a configuration example of a circuit of the semiconductor memory device 101 according to the embodiment. As illustrated in FIG. 1, the semiconductor memory device 101 includes a memory cell array including a plurality of memory cells MCs, a plurality of word lines WLs, and a plurality of bit lines BLs. FIG. 1 illustrates, as an example of the word lines WLs, a word line WLₙ, a word line WLₙ₊₁, and a word line WLₙ₊₂ (where n is a positive integer). FIG. 1 illustrates, as an example of the bit lines BLs, a bit line BLₘ, a bit line BLₘ₊₁, and a bit line BLₘ₊₂ (where m is a positive integer).

The memory cells MCs are arranged, for example, in a matrix and form the memory cell array. Each of the memory cells MCs includes a memory transistor MTR, which is a field effect transistor (FET), and a memory capacitor MCP.

The memory cells MCs that are disposed along a row are connected to a word line WL (e.g., a word line WLₙ) corresponding to the row (e.g., a nth row) to which the memory cells belong. Specifically, the gate of the memory transistor MTR in each of the memory cells MCs is connected to the word line WL corresponding to the row to which the memory cells MCs belong.

The memory cells MCs that are disposed along a column are connected to a bit line BL (e.g., a bit line BLₘ₊₂) corresponding to the column (e.g., (m+2)th column) to which the memory cells belong. Specifically, one of the source or drain of the memory transistor MTR in each of the memory cells MCs is connected to the bit line BL corresponding to the column to which the memory cells MCs belong. The other of the source or drain of the memory transistor MTR is connected to an electrode of the memory capacitor MCP in each of the memory cells MCs.

The memory capacitor MCP stores an electric charge, and as a result, can store data. The memory capacitor MCP includes a capacitor electrode connected to the other of the source or drain of the memory transistor MTR, a capacitor dielectric film, and another capacitor electrode facing the capacitor electrode with the capacitor dielectric film interposed between the capacitor electrodes.

In the configuration described above, under application of a voltage to a predetermined word line WL to turn on a plurality of predetermined memory transistors MTRs that are connected to the predetermined word line WL and under application of a current to a bit line BL connected to a memory transistor MTR for electric charge storage among the memory transistors MTRs, an electric charge can be stored in a memory capacitor MCP connected to the memory transistor MTR through which the word line WL and the bit line BL are connected. Therefore, the memory cells MCs of the memory cell array can each store the data.

### Physical Configuration of Semiconductor Memory Device

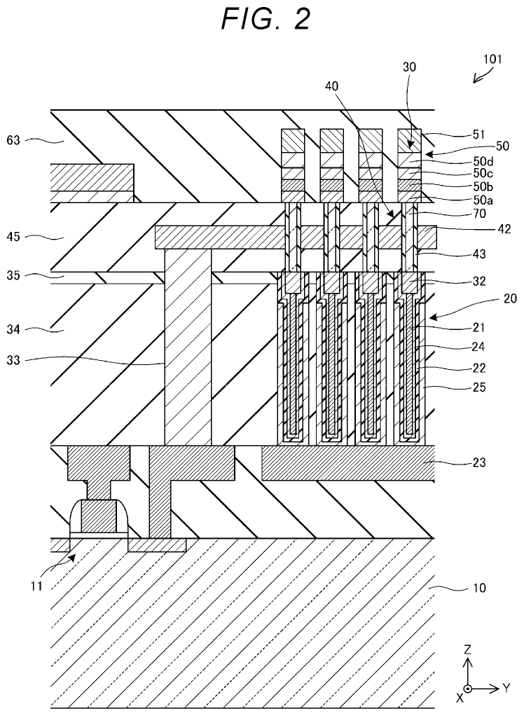

FIG. 2 is a schematic cross-sectional view illustrating a physical configuration example of the semiconductor memory device 101 according to the embodiment. As illustrated in FIG. 2, the semiconductor memory device 101 includes a semiconductor substrate 10, a logical circuit 11, a capacitor 20, a semiconductor device 30, a conductor 33, and insulating layers 34, 35, 45, and 63.

The capacitor 20 corresponds to the memory capacitor MCP of FIG. 1, and includes a conductor 21, a capacitor electrode 24 electrically connected to the conductor 21, a capacitor electrode 25 facing the capacitor electrode 24, an insulating film 22 between the capacitor electrode 24 and the capacitor electrode 25, and a conductor 23 that is electrically connected to the capacitor electrode 25 and applies a constant electric voltage (e.g., ground voltage) to the capacitor electrode 25.

The conductor 21 has an upper end portion in contact with the lower end of a lower electrode 32, and extends downwardly from the upper end portion. The capacitor electrode 24 is electrically connected to the lower electrode 32 and the conductor 21. In the embodiment, the capacitor electrode 24 covers the side surface of the lower electrode 32 and the side surface of the conductor 21. The insulating film 22 covers the side surface of the capacitor electrode 24. The capacitor electrode 25 surrounds the lower side surface and bottom surface of the insulating film 22, and has the lower end in contact with the upper end surface of the conductor 23.

The conductor 21 may include a material such as amorphous silicon. The insulating film 22 may include a material such as hafnium oxide. The conductor 23 and the capacitor electrodes 24 and 25 may include a material such as tungsten (W) and titanium nitride (TiN).

The capacitor 20 according to the embodiment is a pillar-type capacitor extending upwardly or downwardly. A field effect transistor 40 in the semiconductor device 30 according to the embodiment is a vertical transistor including a channel extending upwardly or downwardly as described below. As illustrated in FIG. 2, the capacitor 20 is below the field effect transistor 40.

For example, in the embodiment illustrated in FIG. 2, a vertical straight line including a central axis extending in the upward or downward direction of the capacitor 20 penetrates through the channel extending in the upward or downward direction of the field effect transistor 40. This makes it possible to improve the density of the memory cell array.

As described below, the semiconductor memory device 101 according to the embodiment has at least a part of the logical circuit 11 below the capacitor 20. This makes it possible to further integrate semiconductor memory device. The semiconductor memory device 101 may, however, include another type of capacitor configured to store an electric charge in place of a three-dimensional capacitor described in the embodiment.

The semiconductor device 30 includes the field effect transistor 40 corresponding to the memory transistor MTR of FIG. 1, the lower electrode 32, an upper electrode 50, and a conductive layer 51.

The field effect transistor 40 includes an oxide semiconductor layer 70 that is electrically connected to the lower electrode 32, is on or above the lower electrode 32, and corresponds to the channel of the field effect transistor 40, a gate insulating film 43 surrounding the side surface of the oxide semiconductor layer 70, and a conductive layer 42 facing the oxide semiconductor layer 70 with the gate insulating film 43 interposed therebetween.

The upper electrode 50 is electrically connected to the oxide semiconductor layer 70, and is on or above the oxide semiconductor layer 70. The semiconductor device 30 of the embodiment is on or above the capacitor 20.

The lower electrode 32 has the upper end in contact with the lower end of the oxide semiconductor layer 70 and the lower end in contact with the conductor 21 of the capacitor 20, and thus supplies an electric charge to the capacitor 20. The lower electrode 32 includes, for example, an ITO layer containing a metal oxide such as indium-tin-oxide (ITO).

The oxide semiconductor layer 70 includes an upper end portion corresponding to one of the drain or source of the field effect transistor 40, a lower end portion corresponding to the other of the drain or source, and a central portion that is between the upper end portion and the lower end portion and corresponds to the channel. The oxide semiconductor layer 70 is a column extending upwardly or downwardly. Therefore, the field effect transistor 40 is a so-called vertical transistor.

The oxide semiconductor layer 70 is a semiconductor in which oxygen vacancy acts as a donor, and contains as a metal element indium (In), zinc (Zn), and gallium (Ga). Specifically, the oxide semiconductor layer 70 includes an oxide of indium, gallium, and zinc, that is, InGaZnO (IGZO). The oxide semiconductor layer 70 has, for example, an amorphous structure. The oxide semiconductor layer 70 may be an oxide semiconductor of another type.

The gate insulating film 43 includes, for example, a silicon nitride film (Si₃N₄) containing silicon and nitrogen.

The conductive layer 42 corresponds to the gate electrode of the field effect transistor 40, and faces the central portion between the upper end and lower end of the oxide semiconductor layer 70 with the gate insulating film 43 interposed therebetween. The conductive layer 42 includes, for example, tungsten (W).

The upper electrode 50 includes a metal oxide layer 50a, an intermediate conductive layer 50b, a barrier metal layer 50c, and a metal film 50d.

The upper electrode 50 is in contact with the upper end of the oxide semiconductor layer 70, and is on or above the oxide semiconductor layer 70. As illustrated in FIG. 2, the metal oxide layer 50a in the upper electrode 50 includes a metal oxide containing oxygen, indium, and tin. Specifically, the metal oxide layer 50a forms an electrode (ITO electrode) of indium-tin-oxide (ITO). The metal oxide layer 50a has a thickness of, for example, 1 to 10 nm.

The intermediate conductive layer 50b is electrically connected to the metal oxide layer 50a, and is on the metal oxide layer 50a. The intermediate conductive layer 50b contains oxygen and a first metal that is contained in the barrier metal layer 50c.

In the embodiment, the intermediate conductive layer 50b includes an oxide of titanium (Ti) (an example of the “first metal”), that is, titanium oxide (TiO). The intermediate conductive layer 50b has a thickness of, for example, 1 to 10 nm.

The barrier metal layer 50c is electrically connected to the intermediate conductive layer 50b, and is on the intermediate conductive layer 50b. The barrier metal layer 50c contains the first metal that is contained in the intermediate conductive layer 50b.

In the embodiment, the barrier metal layer 50c includes a barrier metal, for example, titanium nitride (TiN). The barrier metal layer 50c has a thickness of, for example, 1 to 10 nm.

The metal film 50d is electrically connected to the barrier metal layer 50c, and is on or above the barrier metal layer 50c. The metal film 50d includes tungsten (W). The metal film 50d has a thickness of, for example, 10 to 50 nm.

The upper electrode 50 electrically connects the conductive layer 51 (an example of a “signal line”) corresponding to the bit line BL (FIG. 1) to the field effect transistor 40. The conductive layer 51 is on the upper electrode 50 and is in contact with the metal film 50d that is the upper end of the upper electrode 50.

The logical circuit 11 includes a peripheral circuit such as a decoder for selecting one or more memory cells MCs from the memory cells MCs in the semiconductor memory device 101, a sense amplifier that is connected to the bit line BL, and a register including SRAM.

The logical circuit 11 may include a CMOS circuit having a field effect transistor including a P-channel field effect transistor (Pch-FET) and an N-channel field effect transistor (Nch-FET) that are formed by a CMOS process.

The field effect transistor of the logical circuit 11 may include, for example, the semiconductor substrate 10 such as a single crystal silicon substrate. The Pch-FET and the Nch-FET are a so-called lateral (flat) field effect transistor that has a channel region, a source region, and a drain region in the semiconductor substrate 10, and a channel for flowing carriers in the X- or Y-axial direction substantially parallel to the surface of the semiconductor substrate 10 at a region adjacent to the surface of the semiconductor substrate 10. FIG. 2 illustrates an example of the lateral field effect transistor in the logical circuit 11.

The conductor 33 includes wiring that electrically connects the logical circuit 11 to the semiconductor device 30. The conductor 33 may include via wiring extending upwardly or downwardly and wiring extending horizontally. For example, the conductor 33 may include via wiring that extends in the Z-axial direction and connects the word line WL to the logical circuit 11 on the semiconductor substrate 10 as illustrated in FIG. 2. The conductor 33 may include, for example, copper.

The insulating layer 34 is between a plurality of the capacitors 20 and insulates the capacitors 20 from each other. The insulating layer 35 is on or above the insulating layer 34. The insulating layer 45 is between a plurality of the oxide semiconductor layers 70 and insulates the oxide semiconductor layers 70 from each other. The insulating layer 63 is between a plurality of the upper electrodes 50, between a plurality of the conductive layers 51, and on or above the conductive layers 51, insulates the upper electrodes 50 from each other, and insulates the conductive layers 51 from each other.

The insulating layers 34 and 45 include, for example, a silicon oxide film containing silicon and oxygen. To function as a protective layer, the insulating layer 35 includes, for example, a silicon nitride film containing silicon and nitrogen. The insulating layer 63 includes, for example, a silane film containing silicon and hydrogen.

According to the semiconductor memory device 101 having the aforementioned configuration, during writing information, a voltage is applied to the word line WL selected by the logical circuit 11 to pass a current through the field effect transistor 40 connected to the word line WL, and a voltage is applied to the bit line BL selected by the logical circuit 11 to store an electric charge in the memory capacitor MCP through the channel of the field effect transistor 40 from the bit line BL. Thus, the information can be recorded. During reading information, a voltage is applied to the word line WL selected by the logical circuit 11 to pass a current through the field effect transistor 40 connected to the word line WL. At this time, the voltage that varies depending on the presence or absence of an electric charge stored in the memory capacitor MCP, in the bit line BL selected by the logical circuit 11, is sensed, and based on this sensing, the information can be read.

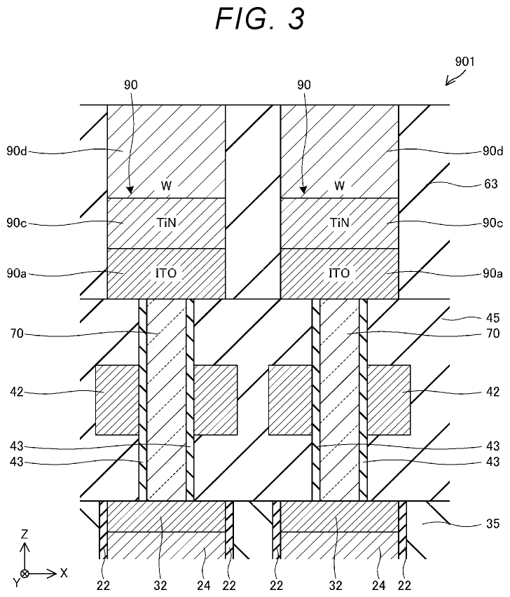

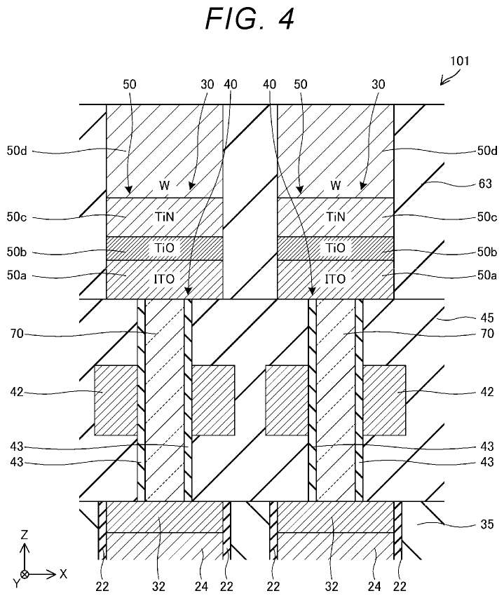

FIG. 3 illustrates an enlarged view of a main part of a semiconductor memory device 901 according to a comparative example. FIG. 4 illustrates an enlarged view of a main part of the semiconductor memory device 101 according to the first embodiment. Some of the configurations of the semiconductor memory device 901 illustrated in FIG. 3 are the same as those of the semiconductor memory device 101 illustrated in FIG. 2. In such situations, a detail description is omitted by giving the same reference numerals and symbols. FIG. 4 corresponds to a cross-sectional view in which the semiconductor memory device is cut along a plane parallel to the ZX plane perpendicular to the extension direction of the conductive layer 42.

A metal oxide layer 90a, a barrier metal layer 90c, and a metal film 90d that constitutes an ITO electrode, are parts of an upper electrode 90 of the semiconductor memory device 901 according to the comparative example as in the upper electrode 50 of the semiconductor memory device 101. The upper electrode 90 of the semiconductor memory device 901 is different from the upper electrode 50 of the semiconductor memory device 101 in that there is no layer corresponding to the intermediate conductive layer 50b.

The inventors of the present application encountered a problem in which peeling occurs in an interface between the metal oxide layer 90a including indium-tin-oxide (ITO) and the barrier metal layer 90c including titanium nitride (TiN) in the semiconductor memory device 901.

The inventors observed that at a time of forming the barrier metal layer 90c on the metal oxide layer 90a, the adhesion at this interface is favorable and peeling does not occur, but that, after forming the metal film 90d including tungsten or the like and the insulating layer 63 including silane (SiH₄) or the like, peeling occurs at this interface. The inventors presumed that one cause of the peeling is a process carried out at a high temperature, and invented the semiconductor memory device 101 according to the embodiment.

Specifically, the barrier metal layer 90c on the metal oxide layer 90a is known to be formed, for example, at a room temperature of 100° C. or lower. The metal film 90d and the insulating layer 63 are known to be formed at a high temperature of 300° C. or higher. For example, a film of tungsten is formed at 350° C., and a film of silane is formed at 400° C. The bond-dissociation energy between indium and oxygen in ITO is generally low.

The inventors discovered that with a reduction in the ratio of oxygen in the ITO layer, the adhesion of a film in contact with the ITO layer is deteriorated. The inventors focused on the following possibility: during formation of the barrier metal layer 90c at a relatively low temperature, indium and oxygen do not dissociate, but during formation of the metal film 90d and formation of the insulating layer 63 at a relatively high temperature, indium and oxygen dissociate in the metal oxide layer 90a, and the dissociated oxygen is diffused into the barrier metal layer 90c.

The inventors discovered that in the vicinity of the interface between the metal oxide layer 90a and the barrier metal layer 90c, the oxygen ratio in the metal oxide layer 90a is reduced, so as to deteriorate the adhesion at the interface, which would be a cause of pecling, and invented the configuration of the upper electrode 50 of the semiconductor memory device 101 according to the embodiment.

Therefore, the upper electrode 50 of the semiconductor memory device 101 according to the embodiment includes the intermediate conductive layer 50b containing the same metal as a metal forming the barrier metal layer 50c and oxygen, between the metal oxide layer 50a and the barrier metal layer 50c.

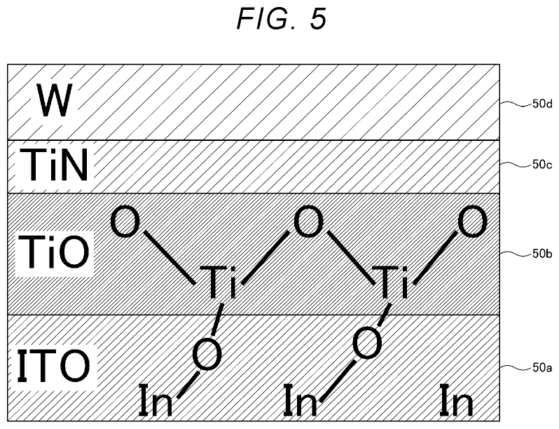

The intermediate conductive layer 50b may be a layer of oxide of the metal forming the barrier metal layer 50c. According to this configuration, a metal (for example, titanium) is oxidized in the intermediate conductive layer 50b as illustrated in FIG. 5, and rich oxygen prevents drawing of oxygen in the metal oxide layer 50a by a metal (for example, titanium) in the intermediate conductive layer 50b.

Therefore, in the vicinity of the interface between the metal oxide layer 50a and the intermediate conductive layer 50b, a reduction in the oxygen ratio in the metal oxide layer 50a is suppressed. This makes it possible to bond, in the metal oxide layer 50a, oxygen in the vicinity of the interface of the intermediate conductive layer 50b to indium in the metal oxide layer 50a, and to bond oxygen in the vicinity of the interface of the intermediate conductive layer 50b to the metal (for example, titanium) in the intermediate conductive layer 50b.

Therefore, even when after formation of the barrier metal layer 50c, the metal film 50d and the insulating layer 63 are formed at a high temperature of 300° C. or higher, dissociation of the bond between indium and oxygen in the metal oxide layer 50a, diffusion of oxygen into the barrier metal layer 50c, and acceleration of peeling can be prevented.

Since the intermediate conductive layer 50b and the barrier metal layer 50c contain the same metal, peeling of the intermediate conductive layer 50b and the barrier metal layer 50c can be further reduced.

The intermediate conductive layer 50b may contain, for example, oxygen, the same metal as the metal in a layer on the intermediate conductive layer 50b, and nitrogen. Therefore, the intermediate conductive layer 50b may include titanium oxynitride (TION), that is, an oxynitride of titanium.

The semiconductor memory device 901 and the semiconductor memory device 101 have been subjected to a tape test defined by JIS standard. During this test, in the semiconductor memory device 901, peeling is observed in the interface between the metal oxide layer 90a and the barrier metal layer 90c.

On the other hand, in the semiconductor memory device 101, peeling is not observed in the interface between the metal oxide layer 50a and the intermediate conductive layer 50b and the interface between the intermediate conductive layer 50b and the barrier metal layer 50c. Therefore, according to a configuration in which the intermediate conductive layer 50b is between the metal oxide layer 50a and the barrier metal layer 50c, peeling caused by ITO can be prevented.

### Second Embodiment

A semiconductor device 130 according to a second embodiment will be described.

Any description between the first embodiment and the following embodiment that is common is omitted, and only different content will be described. In particular, the same operation and effect based on the same configuration is not described here.

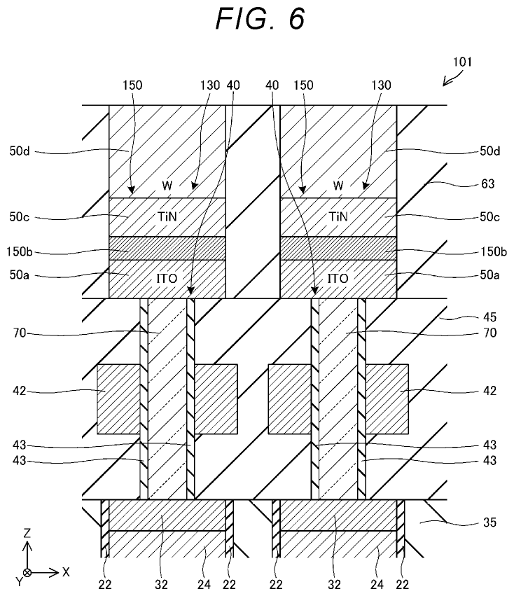

As illustrated in FIG. 6, the semiconductor device 130 according to the second embodiment is different from the semiconductor device 30 according to the first embodiment in FIG. 4 in that an upper electrode 150 is used instead of the upper electrode 50.

The upper electrode 150 includes an intermediate conductive layer 150b instead of the intermediate conductive layer 50b in the upper electrode 50 illustrated in FIG. 4.

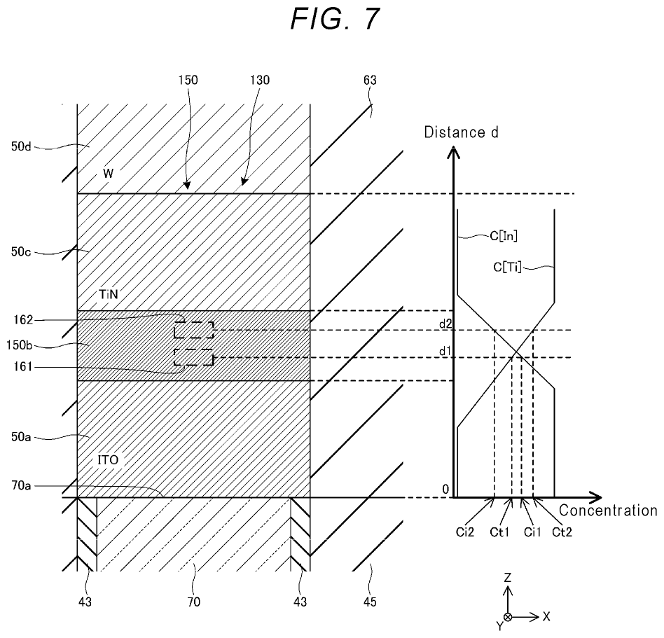

FIG. 7 is a diagram illustrating a change in an indium concentration and a titanium concentration in the intermediate conductive layer 150b relative to a distance from an upper end 70a of the oxide semiconductor layer 70.

FIG. 7 is a graph showing a change in the indium concentration and the titanium concentration in the intermediate conductive layer 150b relative to the distance d from the upper end 70a of the oxide semiconductor layer 70.

In the graph, the horizontal axis represents the concentration of indium or titanium, and the vertical axis represents the distance d from the upper end 70a of the oxide semiconductor layer 70. C[In] and C[Ti] represent the change in the indium concentration and the titanium concentration, respectively, relative to the distance d.

As shown in FIG. 7, the intermediate conductive layer 150b includes a portion 161, and a portion 162.

The portions 161 and 162 are, for example, a virtual rectangular parallelepiped contained in the intermediate conductive layer 150b. The portions 161 and 162 may have any shape such as a sphere or a cube.

The center of the portion 161 is positioned such that the distance d from the upper end 70a of the oxide semiconductor layer 70 is, for example, d1. The center of the portion 162 is positioned such that the distance d from the upper end 70a of the oxide semiconductor layer 70 is, for example, d2 that is greater than d1.

The portion 161 contains titanium, for example, at an average concentration Ct1. The portion 162 contains titanium, for example, at an average concentration Ct2. The concentration Ct2 is higher than the concentration Ct1.

The portion 161 contains indium, for example, at an average concentration Ci1. The portion 162 contains indium, for example, at an average concentration Ci2. The concentration Ci2 is lower than the concentration Ci1.

In the intermediate conductive layer 150b, the total atomic percent of oxygen, indium, tin, titanium, and nitrogen is 80% or more.

The intermediate conductive layer 150b is formed, for example, by supplying gases with the gas concentration being continuously changed in the same chamber.

Specifically, the intermediate conductive layer 150b is a layer in which the metal oxide layer 50a and the barrier metal layer 50c are mixed. The inside of the intermediate conductive layer 150b that is closer to the metal oxide layer 50a exhibits a property closer to the metal oxide layer 50a.

Therefore, in the vicinity of the metal oxide layer 50a in the intermediate conductive layer 150b, titanium exists, but indium is abundant. Accordingly, in the vicinity of the interface between the metal oxide layer 50a and the intermediate conductive layer 150b, a reduction in the oxygen ratio in the metal oxide layer 50a is reduced.

In the metal oxide layer 50a, oxygen in the vicinity of the interface of the intermediate conductive layer 150b is bound to indium in the metal oxide layer 50a, and at the same time, is bound to rich indium or titanium in the intermediate conductive layer 150b. Therefore, peeling of the metal oxide layer 50a and the intermediate conductive layer 150b can be effectively prevented.

The inside of the intermediate conductive layer 150b that is closer to the barrier metal layer 50c exhibits a property closer to the barrier metal layer 50c. Therefore, in the vicinity of the barrier metal layer 50c in the intermediate conductive layer 150b, indium also exists, but titanium is abundant. Since in the vicinity of the interface between the intermediate conductive layer 150b and the barrier metal layer 50c, both the intermediate conductive layer 150b and the barrier metal layer 50c are rich in the same metal, that is, titanium, peeling of the intermediate conductive layer 150b and the barrier metal layer 50c also can be suppressed.

The configuration in which the portion 161 contains a lower concentration of titanium and a higher concentration of indium than the portion 162 is described above. Alternatively, the lower concentration of titanium and the higher concentration of indium provided in the portion 161 may be provided in separate portions of the intermediate conductive layer 150b, and the higher concentration of titanium and the lower concentration of indium provided in the portion 162 may be provided in separate portions of the intermediate conductive layer 150b.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first electrode;
an oxide semiconductor layer electrically connected to the first electrode and disposed above the first electrode;
a gate electrode facing the oxide semiconductor layer with an insulating film interposed therebetween; and
a second electrode including a first conductive layer electrically connected to the oxide semiconductor layer and disposed above the oxide semiconductor layer, the first conductive layer containing oxygen, indium, and tin,
wherein the second electrode further includes a second conductive layer in contact with the first conductive layer and containing oxygen and a first metal and a third conductive layer in contact with the second conductive layer and containing the first metal.

2. The semiconductor device according to claim 1, wherein the first metal is titanium, and the second conductive layer includes a layer including titanium oxide or titanium oxynitride.

3. The semiconductor device according to claim 1, wherein
the first metal is titanium, and
the second conductive layer has a first portion that is at a first distance from an upper end of the oxide semiconductor layer and contains titanium at a first titanium concentration, and a second portion that is at a second distance greater than the first distance and contains titanium at a second titanium concentration higher than the first titanium concentration.

4. The semiconductor device according to claim 3, wherein the second conductive layer has a third portion that is at a third distance from an upper end of the oxide semiconductor layer and contains indium at a first indium concentration, and a fourth portion that is at a fourth distance greater than the third distance and contains indium at a second indium concentration lower than the first indium concentration.

5. The semiconductor device according to claim 4, wherein the first portion and the third portion are the same portion of the second conductive layer, and the second portion and the fourth portion are the same portion of the second conductive layer.

6. The semiconductor device according to claim 4, wherein the first portion and the third portion are different portions of the second conductive layer, and the second portion and the fourth portion are different portions of the second conductive layer.

7. The semiconductor device according to claim 4, wherein the second conductive layer includes oxygen, indium, tin, titanium, and nitrogen at a total atomic percent of 80% or more.

8. The semiconductor device according to claim 3, wherein the second conductive layer includes oxygen, indium, tin, titanium, and nitrogen at a total atomic percent of 80% or more.

9. The semiconductor device according to claim 1, further comprising:
a pad electrically connected to the third conductive layer and disposed above the third conductive layer, the pad containing a second metal that is different from the first metal; and
a signal line electrically connected to the pad and disposed above the pad.

10. The semiconductor device according to claim 1, wherein the third conductive layer is a barrier metal layer.

11. A semiconductor memory device comprising:
a first electrode;
an oxide semiconductor layer electrically connected to the first electrode and disposed above the first electrode;
a gate electrode facing the oxide semiconductor layer with an insulating film interposed therebetween;
a second electrode including a first conductive layer electrically connected to the oxide semiconductor layer and disposed above the oxide semiconductor layer, the first conductive layer containing oxygen, indium, and tin, wherein the second electrode further includes a second conductive layer in contact with the first conductive layer and containing oxygen and a first metal and a third conductive layer in contact with the second conductive layer and containing the first metal;
a third electrode electrically connected to the first electrode;
a fourth electrode facing the third electrode; and
a dielectric film between the third electrode and the fourth electrode.

12. The semiconductor memory device according to claim 11, wherein the first metal is titanium, and the second conductive layer includes a layer including titanium oxide or titanium oxynitride.

13. The semiconductor memory device according to claim 11, wherein
the first metal is titanium, and
the second conductive layer has a first portion that is at a first distance from an upper end of the oxide semiconductor layer and contains titanium at a first titanium concentration, and a second portion that is at a second distance greater than the first distance and contains titanium at a second titanium concentration higher than the first titanium concentration.

14. The semiconductor memory device according to claim 13, wherein the second conductive layer has a third portion that is at a third distance from an upper end of the oxide semiconductor layer and contains indium at a first indium concentration, and a fourth portion that is at a fourth distance greater than the third distance and contains indium at a second indium concentration lower than the first indium concentration.

15. The semiconductor memory device according to claim 14, wherein the first portion and the third portion are the same portion of the second conductive layer, and the second portion and the fourth portion are the same portion of the second conductive layer.

16. The semiconductor memory device according to claim 14, wherein the first portion and the third portion are different portions of the second conductive layer, and the second portion and the fourth portion are different portions of the second conductive layer.

17. The semiconductor memory device according to claim 14, wherein the second conductive layer includes oxygen, indium, tin, titanium, and nitrogen at a total atomic percent of 80% or more.

18. The semiconductor memory device according to claim 13, wherein the second conductive layer includes oxygen, indium, tin, titanium, and nitrogen at a total atomic percent of 80% or more.

19. The semiconductor memory device according to claim 11, further comprising:
a pad electrically connected to the third conductive layer and disposed above the third conductive layer, the pad containing a second metal that is different from the first metal; and
a signal line electrically connected to the pad and disposed above the pad.

20. The semiconductor memory device according to claim 11, wherein the third conductive layer is a barrier metal layer.
